(19) United States
(12) Patent Application Publication
(10) Pub. No.: US 2009/0309214 A1
(43) Pub. Date: Dec. 17, 2009

(54) Circuit Module Turbulence Enhancement

(75) Inventors: Leland Szewerenko, Pittsburgh, PA (US); Julian Partridge, Austin, TX (US); Wayne Lieberman, Austin, TX (US); Paul Goodwin, Austin, TX (US)

Correspondence Address: FISH & RICHARDSON P.C., P.O BOX 1022, Minneapolis, MN, 55440-1022, US

(73) Assignee: Entorian Technologies, LP

(21) Appl. No.: 12/546,350

(22) Filed: Aug. 24, 2009

Related U.S. Application Data
(63) Continuation of application No. 11/332,740, filed on Jan. 13, 2006, now Pat. No. 7,579,687.

(51) Int. Cl. H01L 23/34; H01L 21/00; H05K 7/20

(52) U.S. Cl. 257/707; 257/713; 257/717; 257/720; 257/724; 361/707; 361/709; 361/711; 257/E23.008; 257/E23.051; 257/E23.065; 257/E23.167; 257/E23.177

(57) ABSTRACT

Turbulence inducers are provided on circuit modules. Rising above a substrate or heat spreader surface, turbulence generators may be added to existing modules or integrated into substrates or heat spreaders employed by circuit modules constructed according to traditional or new technologies.

### RELATED APPLICATIONS

This application is a continuation of U.S. patent application Ser. No. 11/332,740 filed Jan. 13, 2006, now U.S. Pat. No. 7,579,687, which is hereby incorporated by reference herein.

### FIELD

The present invention relates to systems and methods for improving the thermal performance of high density circuit modules and, in particular, to systems and methods that enhance the efficiency of air cooling DIMMs and similar modules.

### BACKGROUND

Memory expansion is one of the many fields where high density circuit module solutions provide space-saving advantages. For example, the well-known DIMM (Dual In-line Memory Module) has been in use for years, in various forms, to provide memory expansion. A typical DIMM includes a conventional PCB (printed circuit board) with memory and supporting digital logic devices mounted on both sides. The DIMM is typically mounted in an area of the host computer system by inserting a contact-bearing edge of the DIMM into a card edge connector.

DIMMs and other circuit modules generate heat. As operating speeds and capacities have increased, systems and methods to shed heat have become more valuable. A variety of systems and methods have been used to dissipate heat from operating circuit modules. For example, forced air has been used for years to cool circuit modules. Heat sinks have also been employed to increase the surface area of a circuit or module and, consequently, increase the surface area from which heat may be conducted to surrounding air. Consequently, many systems have combined forced air flow with increased surface area to provide a system devised to mitigate heat accumulation in DIMMs and other circuitry operating under demanding conditions.

There are, however, reasonable limits to the speeds that may be imparted to air passing over a circuit module. Further, heat sinks increase surface conduction area but do little more. Consequently, what is needed are systems and methods to improve the conduction between a circuit module and nearby airflow.

### SUMMARY

Turbulence inducers are provided on circuit modules. Rising above a substrate or heat spreader surface, turbulence generators may be added to existing modules or integrated into substrates or heat spreaders employed by circuit modules constructed according to traditional or new technologies.

### BRIEF DESCRIPTION OF THE DRAWINGS

FIG. 1 is a perspective view of a module devised in accordance with a preferred embodiment of the present invention.

FIG. 2 is a cross-sectional view of a module taken along a line corresponding to line A-A of FIG. 1.

FIG. 3 is an enlarged depiction of a portion of a module and a turbulence inducement clip devised in accordance with a preferred embodiment of the present invention.

FIG. 4 illustrates an exploded view of a turbulence inducer clip devised for use with a circuit module in accordance with a preferred embodiment of the present invention.

FIG. 5A depicts a circuit module devised in accordance with an alternative embodiment of the present invention.

FIG. 5B depicts a circuit module devised in accordance with an alternative preferred embodiment of the present invention.

FIG. 5C depicts a cross-sectional view of a circuit module devised in accordance with an alternative embodiment of the present invention.

FIG. 6 depicts a rigid substrate that may be employed in accordance with a preferred embodiment of the present invention.

FIG. 7 depicts a flex circuit that may be employed in a module in accordance with a preferred embodiment of the present invention.

FIG. 8 is an exploded view illustrating how a substrate and flex circuit may be combined in accordance with a preferred embodiment of the present invention.

FIG. 9 is a cross-sectional depiction of a module devised in accordance with an alternate preferred embodiment of the present invention.

### DETAILED DESCRIPTION OF PREFERRED EMBODIMENTS

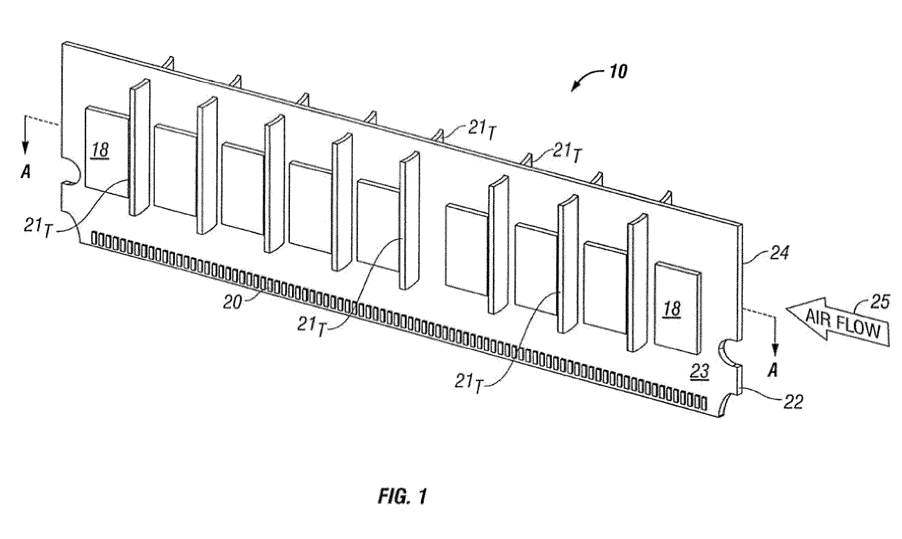

FIG. 1 is a perspective view of a module devised in accordance with a preferred embodiment of the present invention. FIG. 1 depicts a conventional circuit module 10 with plural ICs 18 which, in a preferred embodiment, will typically be memory integrated circuits in chip scale packages (CSP). After appreciating this specification, those of skill will, however, note that many types of circuit modules in addition to those with a primary function of memory may benefit from employment of the invention. For example, the invention may be employed with graphics, communications, dedicated computing or other circuit modules where heat extraction is a valued attribute.

In depicted module 10 of FIG. 1, a substrate 22 is populated along each of its surfaces 23 and 24 with plural ICs 18 and exhibits plural contacts 20 configured for insertion into an edge connector socket. It should be understood that the depiction is merely exemplary and the invention is applicable to a wide variety of module constructions both conventional and new, a few example types of which are depicted in later Figs. In the embodiment depicted in FIG. 1, substrate 22 is typically FR4 as commonly found in traditional DIMMs.

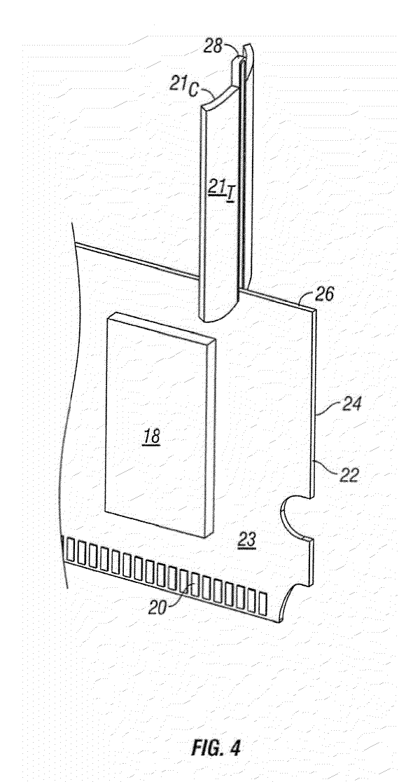

Turbulence inducers 21T project from side or surface 23 (as well as the other side 24 in preferred embodiments) of substrate 22. Preferably, turbulence inducers 21T are disposed between ICs 18 disposed along the sides of substrate 22 and may either be integral with substrate 22 or added to module 10 by, for example, being configured as part of a clip for placement over upper edge 26 of substrate 22 as shown in later FIG. 4. Turbulence inducers 21T may be devised of any material with thermally conductive materials being preferred. As those of skill will recognize, turbulence inducers, such as those examples shown in FIG. 1 which are oriented perpendicularly to air flow 25, as well as the long axis of module 10 disturb the laminar air flow and thereby induce mixing of the air passing by module 10. This causes a more uniform heat distribution through the air proximal to module 10 and, therefore, encourages thermal shedding from module 10.

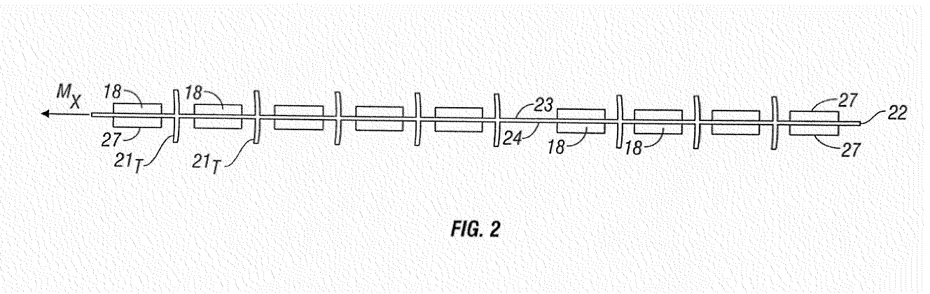

FIG. 2 is a cross-sectional view of a module 10 taken along a line corresponding to line A-A of FIG. 1. Turbulence inducers 21T are shown emergent or rising from sides or surfaces 23 and 24 above the level of upper surfaces 27 of the resident ICs 18 populated along substrate 22. Those of skill will appreciate that the dimensional aspects shown are for illustrative purposes. In the depiction of FIG. 2, turbulence inducers 21T are represented as being configured as a part of substrate 22 and emergent from surfaces 23 and 24 in a direction substantially perpendicular to module long axis M_{X}. In particular, where configured as part of the substrate and particularly if the turbulence inducers can be thermally connected to a core of the substrate, thermal performance may be improved both by conduction from the inducer as well as the disturbance of the laminar air flow induced by the projection of the turbulence inducers into the airflow thus providing two phenomena that can contribute to module cooling. Under some circumstances, however, such integral constructions may be more difficult to implement.

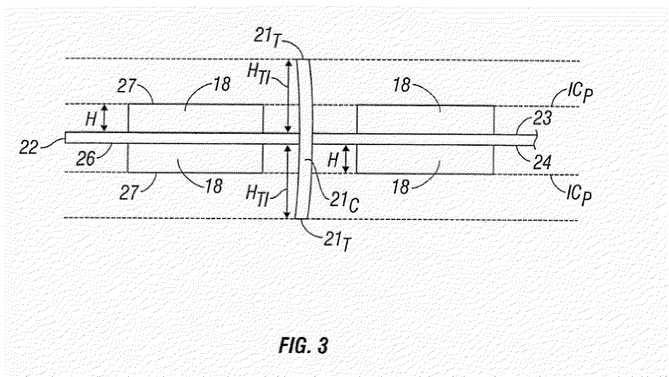

FIG. 3 is an enlarged depiction of another preferred embodiment in accordance with the present invention. In the exemplar depiction of FIG. 3, two-sided turbulence inducer clip 21 C is depicted disposed over upper edge 26 of substrate 22 of module 10. Turbulence inducers 21T, whether integral with the substrate with which they employed or configured as a separate piece comprising a pair of inducers, as exemplified by the clip depiction of FIG. 3, should be selected and devised to balance the competing considerations of sufficient turbulence generation and excessive obstruction of the air flow 25. As depicted, turbulence inducers 21T have a height “H_{TI}” above the respective surface of the substrate. In a preferred embodiment, the height “H_{TI}” of turbulence inducers 21T is greater than height “H” which is defined to be the distance from the side of the substrate that is populated with the respective ICs to the upper surface of the respective ICs. When modules that employ a flex circuit disposed about a rigid substrate employ turbulence inducers in accordance with the invention, an embodiment of which is shown in later Figs. herein, height H_{TI} is the height of the turbulence inducer above the populated flex circuit 12 while “H” is the distance above the populated flex circuit 12 to which the respective IC rises as determined by its upper surface 27.

FIG. 4 illustrates an exploded view of a two sided turbulence inducer clip 21C devised for use with a circuit module in accordance with a preferred embodiment of the present invention. As shown in FIG. 4, two-sided turbulence inducer clip 21C is comprised of first and second turbulence inducers 21T connected through connective member 28. Inducer clip 21C is placed over upper edge 26 of substrate 22 to position the first turbulence inducer of the clip between a pair of integrated circuits on a first side of the substrate and the second turbulence inducer of the clip between a second pair of integrated circuits on the second side of the substrate to provide turbulence inducement for circuit modules that employ substrates not originally configured with such inducers. Inducer clip 21C may be made of any configurable material but thermally conductive materials are preferred. Further, as those of skill will recognize, it need not be positioned to result in placement of the turbulence inducers 21T of clip 21C between integrated circuits. Placement adjacent to integrated circuits is also likely to encourage turbulence in proximal airflow.

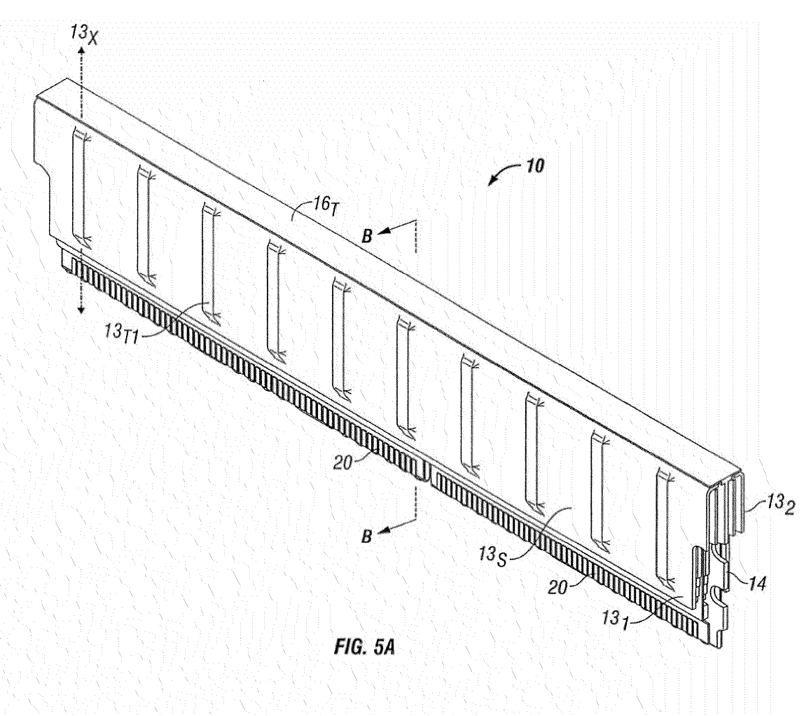

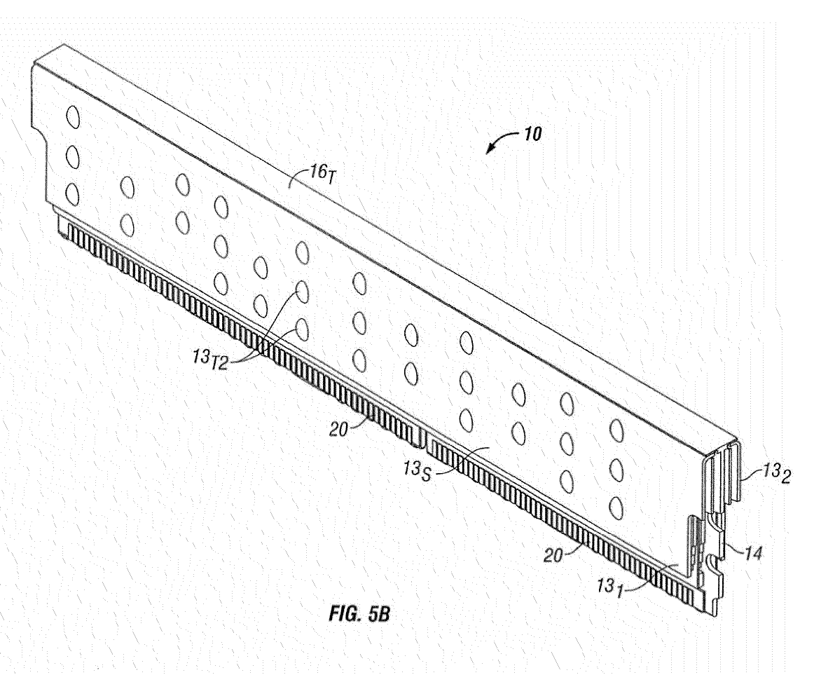

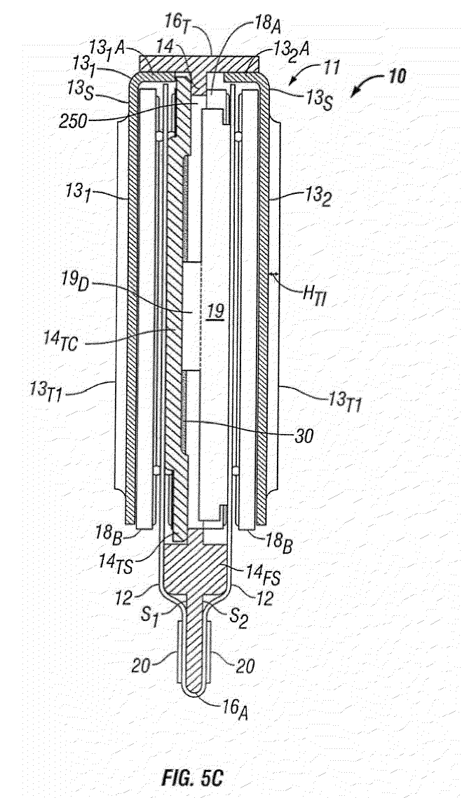

FIG. 5A depicts a circuit module 10 having thermal spreaders 13₁ and 13₂ configured with turbulence inducers 13T1 in accordance with a preferred embodiment of the present invention. The depictions illustrate module 10 having substrate 14 about which is disposed flex circuit 12 populated with ICs 18 which are, in a preferred embodiment, integrated circuitry in CSP packages. ICs 18 are, in this preferred embodiment, CSP packaged memory devices of small scale. For purposes of this disclosure, the term chip-scale or “CSP” shall refer to integrated circuitry of any function with an array package providing connection to one or more die through contacts (often embodied as “bumps” or “balls” for example) distributed across a major surface of the package or die. CSP does not refer to leaded devices that provide connection to an integrated circuit within the package through leads emergent from at least one side of the periphery of the package such as, for example, a TSOP.

Embodiments of the present invention may be employed with modules populated with ICs that are leaded or CSP or in packaged or unpackaged forms but where the term CSP is used, the above definition for CSP should be adopted. Consequently, references to CSP are to be broadly construed to include the large variety of array devices (and not to be limited to memory only) and whether die-sized or other size such as BGA and micro BGA as well as flip-chip. As those of skill will understand after appreciating this disclosure, some embodiments of the present invention may be devised to employ stacks of ICs each disposed where an IC 18 is indicated in the exemplar Figs.

Multiple integrated circuit die may be included in a package depicted as a single IC 18. While in this embodiment memory ICs are used to provide a memory expansion board or module, various embodiments may include a variety of integrated circuits and other components and may be directed principally to functions other than or in addition to memory. Such variety may include processors—whether general purpose or function specific such as graphics, FPGA's, RF transceiver circuitry, and digital logic as a list of non-limiting examples, while primary module functions may include, as a non limiting list of examples, memory, graphics, communications, and computing to name just a few examples. Some modules in accordance with a preferred embodiment will exhibit plural ICs of a first type, such as memory CSPs, for example, and will have at least one IC of a second type, such as a microprocessor, graphics processor or buffer or, more particularly, an AMB, for example. Other modules will exhibit ICs of only a first type such as memory CSPs, for example, while other modules may exhibit many types of ICs such as, for example, memory ICs, logic ICs, and one or more buffer ICs.

Some alternative embodiments will have a separate flex circuit on each side of substrate 14. Substrate 14 is shown with an optional extension 16T which, in this embodiment, is integral with the body of substrate 14.

Optional extension 16T may be devised in a variety of configurations and need not extend laterally from the main axis of substrate 14 in both directions. For example, extension 16T may extend from substrate 14 in only one direction and need not project perpendicular from the body of substrate 14.

Preferably, substrate 14 is comprised of thermally conductive material. For example, aluminum, like many other metallic materials, is thermally conductive and may be readily manipulated for configuration as substrate 14. Carbon-based materials and certain plastics, for example, are known to readily conduct thermal energy and, as alternatives to metallic materials, such materials may be employed to advantage where metallic materials are not available or wanted.

In the depicted embodiment of FIG. 5A, thermal spreaders 13₁ and 13₂ are preferably thermally connected to ICs 18 and substrate 14. Thermal spreaders 13₁ and 13₂ are comprised of thermally conductive material with higher conductivity metallic materials being preferred. Aluminum is a preferred choice for thermal spreaders in this embodiment due to its amenability to fabrication and relatively high thermal conductivity. Those of skill will, however, recognize that use of copper and copper alloys for thermal spreaders 13₁ and 13₂ will typically provide even greater thermal benefits although at typically a higher cost. Thermal spreaders 13₁ and 13₂ are preferably thermally connected to ICs 18 (or other ICs where accessible) with thermal adhesive. Turbulence inducers 13T1 are formed in thermal spreaders 13₁ and 13₂ to disturb the laminar flow of air along module 10 that is typically encountered in circuit module applications and, in this embodiment, are laterally oriented to be substantially parallel with an axis 13_{X} that is substantially perpendicular to the module axis of module 10.

In the depicted embodiment of FIG. 5B, thermal spreaders 13₁ and 13₂ are thermally connected to ICs 18 and substrate 14. Turbulence inducers 13T2 are formed in thermal spreaders 13₁ and 13₂ and, in this embodiment, are of a type that rises above surface 13S of thermal spreaders 13₁ and 13₂ to disturb the laminar flow of air along module 10 that is typically encountered in circuit module applications. Unlike those turbulence inducers 13T1 shown in FIG. 5A, the turbulence inducers 13T2 shown in FIG. 5B are not characterized as each being oriented perpendicularly to the lengthwise orientation or module axis of module 10.

FIG. 5C depicts a cross-sectional view of a module 10 devised in accordance with an alternative preferred embodiment. FIG. 5C is a cross-sectional view of an exemplar module 10 that employs a larger IC 19 such as an AMB 19. The view of FIG. 5C is along a line near the center of the depicted exemplar module and along a line that corresponds to line B-B shown in FIG. 5A. As shown in FIG. 5C, an optional thermal sink 14TS is in thermal contact with AMB 19. Thermal sink 14TS is comprised, in this preferred embodiment, from metallic material of high thermal conductivity such as, for example, copper or copper alloy and has, in this preferred embodiment, a central portion 14TC that is a copper field substantially larger than and preferably in thermal contact with IC (AMB in this embodiment) 19. AMB die 19D is in contact with area 14TC of thermal sink 14TS either directly, or through thermally conductive adhesive 30 or a thermally conductive gasket material, for example. Thermal contact with a part of circuit 19 should be considered thermal contact with circuit 19.

In this preferred embodiment, central portion 14TC of thermal sink 14TS is raised above the periphery of thermal sink 14TS and additionally provides an indentation into which may be introduced at least a portion of AMB circuit 19 such as, for example, AMB die 19D, to assist in realization of a low profile for module 10. Neither thermal sink 14TS nor an indentation are required, however, to practice the invention. In the preferred depicted embodiment, thermal sink 14TS is disposed over a window 250 through substrate 14. AMB circuit 19, which is mounted on the “inside” of flex circuit 12, is disposed, at least in part, into window 250 from the “back” side of substrate 14 to realize thermal contact with thermal sink 14TS to provide a conduit to reduce thermal energy loading of AMB circuit 19.

Thermal sink 14TS need not cover the entirety of window 250. In other embodiments, for example, thermal sink 14TS may merely be across the window 250 or thermal sink 14TS may be set into window 250 instead of over or across the opening of window 250. Thermal sink 14TS is typically a separate piece of metal from substrate 14 but, after appreciating this specification, those of skill will recognize that, in alternative instances, thermal sink 14TS may be integral with substrate 14 or a particular portion of substrate 14 may be constructed to be a thermal sink 14TS in accordance with the teachings herein. For example, substrate 14 may be comprised of aluminum, while a thermal sink area 14TS of substrate 14 may be comprised of copper yet substrate 14 and thermal sink 14TS are of a single piece. In a variation of the integral thermal sink-substrate embodiment, the thermal sink could be attached to the substrate without a window and thus be preferentially accessible only on one side of substrate 14. Construction expense will be more likely to militate against such construction but the principles of the invention encompass such constructions. Consequently, a window in substrate 14 is not required to practice some embodiments of the invention. Therefore, a thermal sink 14TS should be considered to be an area or element integral with or attached to a substrate 14 and the material from which that thermal sink is composed exhibits greater thermal conductivity than the material of the substrate. To continue the example, substrate 14 may be aluminum while thermal sink 14TS is comprised of copper.

Substrate 14 has first and second lateral sides identified as S1 and S2. Flex 12 is wrapped about perimeter edge 16A of substrate 14. Some alternative embodiments may employ individual flex circuits on each side of substrate 14. As shown in FIG. 5C, AMB circuit 19 is mounted on the inner side of flex circuit 12. When flex circuit 12 is disposed about substrate 14, AMB circuit 19 is introduced, at least in part, into window 250 with AMB die 19D being disposed, preferably, in thermal contact with thermal sink 14TS of substrate 14. That thermal contact is preferably through thermally conductive adhesive 30 but, in an alternative embodiment, another preferred construction may place AMB die 19D in direct physical contact with thermal sink 14TS to realize the thermal contact or connection between AMB circuit 19 and thermal sink 14TS. Other thermal conduction enhancing materials may also be used in place of, or addition to thermal adhesive 30 such as for example, thermal grease or a thermal gasket.

In FIG. 5C, thermal spreaders 131 and 132 exhibit optional thermal spreader extensions 13₁A and 13₂A which in cooperation with substrate extension 16T provide a thermal conduction path between substrate 14 and thermal spreaders 13₁ and 13₂ and, therefore, between inner ICs 18A (a part of which ICs can be seen in the view) and thermal spreaders 13₁ and 13₂. Extensions 13₁A and 13₂A also, as shown, in cooperation with extension 16T, form a thermally conductive enclosure 11 over module 10. Turbulence inducers 13T1 are shown on each side of module 10 and rise to a height H_{TI} above surfaces 13S of thermal spreaders 13₁ and 13₂, respectively.

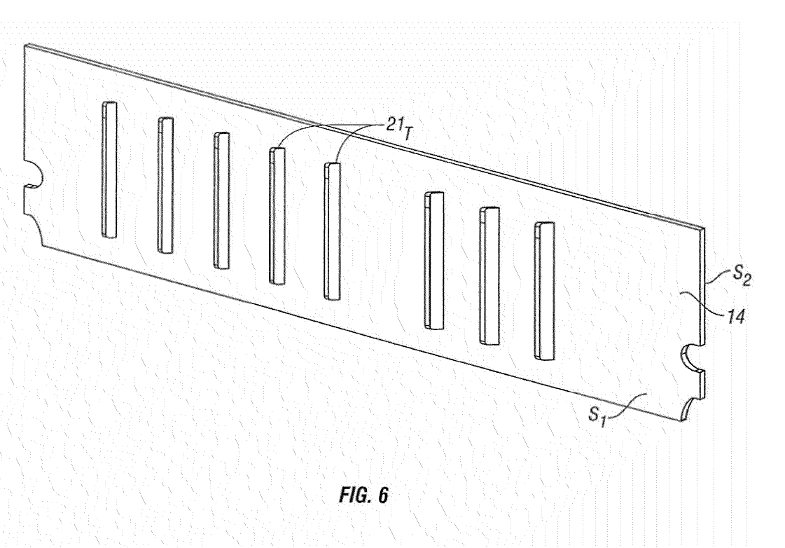

FIG. 6 depicts a rigid substrate that may be employed in accordance with a preferred embodiment of the present invention. Depicted substrate 14 is devised for use with one or more flex circuits that are populated with ICs. Substrate 14 exhibits turbulence inducers 14T which extend from surfaces or sides S1 and S2 of substrate 14.

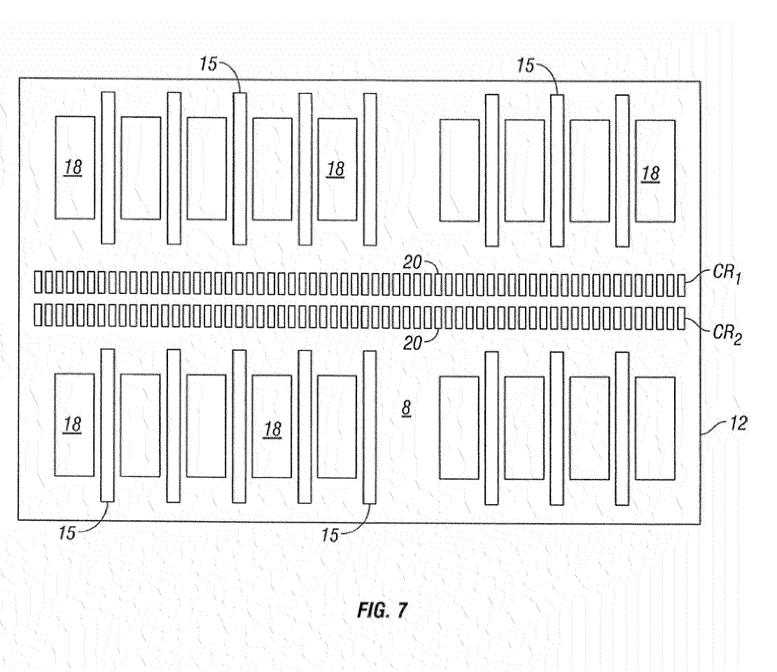

FIG. 7 depicts a flex circuit that may be employed to advantage in a module with substrate devised such as the example substrate 14 shown in earlier FIG. 6. Exemplar flex circuit 12 as depicted in FIG. 7, is prepared for population with integrated circuits and, in this depiction, is represented as being populated with first and second fields or ranks of ICs 18 with contacts 20 being disposed between said ranks or fields of ICs 18 and arranged in two pluralities CRI and CR2. Other embodiments may have other numbers of ranks and combinations of plural ICs connected to create the module of the present invention.

Contacts 20 are configured for insertion in an edge connector socket after flex circuit 12 is disposed about an end of substrate 14. After flex circuit is assembled with substrate 14, those of skill will recognize that contacts 20 may appear on one or both sides of module 10 depending on the mechanical contact interface particulars of the application. Other embodiments may employ flex circuitry that exhibits contacts closer to an edge of the flex circuit.

Slots 15 are provided in flex circuit 12 between integrated circuit locations to allow turbulence inducers 21T of a substrate about which the flex circuit is disposed to emerge from flex circuit slots 15 when flex circuit 12 is disposed about an edge of exemplar substrate 14, for example.

One or both sides of flex circuit 12 may be populated with circuitry such as ICs 18 and, in some embodiments, other ICs such as AMBs may be employed with flex circuit 12 when, for example, a fully-buffered DIMM circuit is implemented.

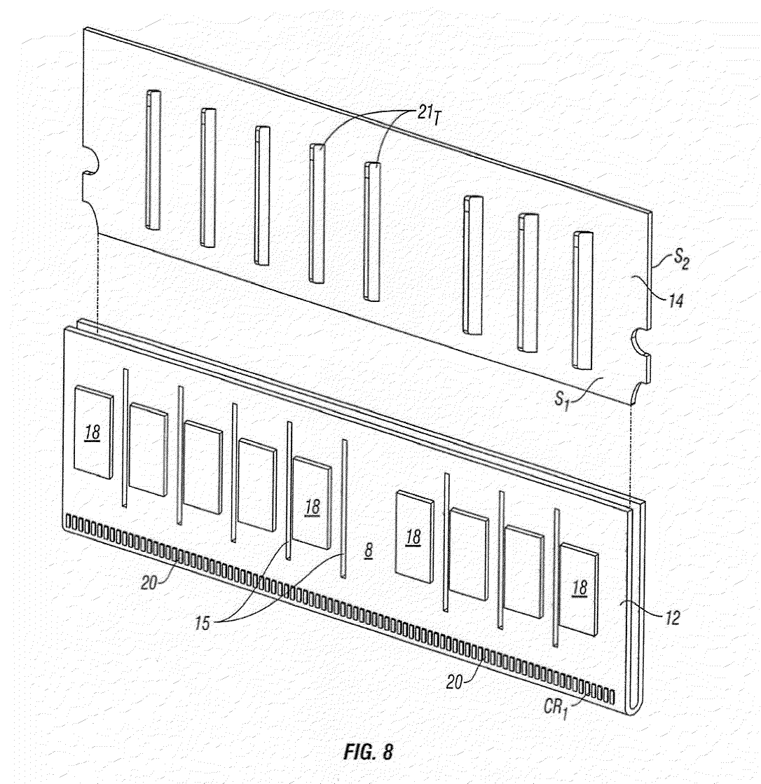

FIG. 8 is an exploded depiction of flex circuit 12 and substrate 14 showing an example disposition of flex circuit 12 about a substrate to allow turbulence inducers 21T that emerge from the surfaces of rigid substrate 14 to emerge from slots 15 of flex circuit 12 and rise above the upper surfaces of the ICs 18 that populated the flex circuit 12 and, thereby, be positioned to mix the airflow near the module.

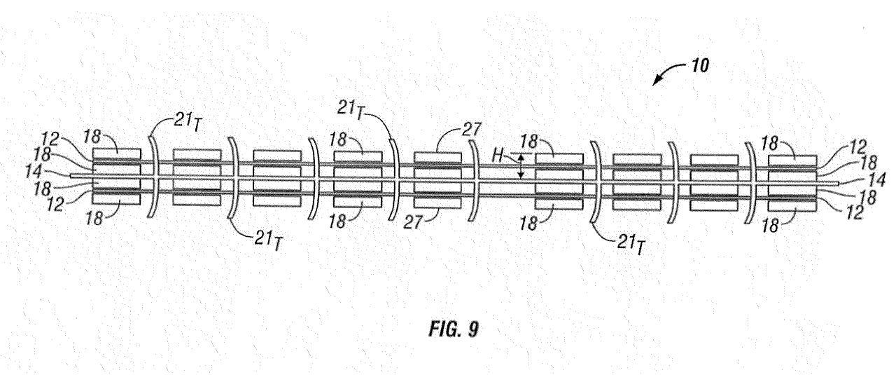

FIG. 9 is a cross-sectional depiction of another preferred embodiment of a module devised in accordance with the present invention. In the depicted example module 10, flex circuit 12 has been populated on each of its two sides with ICs 18 and disposed about substrate 14. Flex circuit 12 exhibits slots 15 as shown in earlier FIG. 7 to allow turbulence inducers 21T to emerge above the upper surfaces 27 of the ICs 18 that are along the outer side of flex circuit 12. In this example, the height “H” above which turbulence inducers 21T project is determined by an imaginary plane defined by the upper surfaces of the outer ICs 18.

Although the present invention has been described in detail, it will be apparent to those skilled in the art that many embodiments taking a variety of specific forms and reflecting changes, substitutions and alterations can be made without departing from the spirit and scope of the invention. Therefore, the described embodiments illustrate but do not restrict the scope of the claims.

1. A circuit module comprising:
a rigid substrate having opposing first and second lateral sides populated with plural integrated circuits each one of which plural integrated circuits having an upper surface that defines a height H that is the distance to which each one of the plural integrated circuits rises above the first or second lateral sides, respectively, of the rigid substrate upon which the respective one of the plural integrated circuits is populated;
plural turbulence inducers that project outward from at least one of the opposing first and second lateral sides of the rigid substrate to a height H_{TI} which exceeds H.

2. The circuit module of claim 1 in which the plural turbulence inducers are each oriented substantially perpendicularly to an axis of the circuit module.

3. The circuit module of claim 1 in which the rigid substrate is comprised of FR4 and the integrated circuits are memory CSPs.

4. The circuit module of claim 1 in which the circuit module is a DIMM.

5. The circuit module of claim 3 in which the circuit module further includes an AMB.

6. The circuit module of claim 1 in which the plural turbulence inducers are comprised of thermally conductive material.

7. The circuit module of claim 1 in which the plural turbulence inducers are comprised of non-metallic material.

8. The circuit module of claim 1 in which the circuit module has memory as a primary function.

9. The circuit module of claim 1 in which each of the plural turbulence inducers is comprised of plastic.

10. The circuit module of claim 1 installed in a computer.
